(19) United States
(12) Patent Application Publication
(10) Pub. No.: US 2023/0085722 A1
(43) Pub. Date: Mar. 23, 2023

(54) SEMICONDUCTOR STORAGE DEVICE

(71) Applicant: Kioxia Corporation, Tokyo (JP)

(72) Inventors: Jieqiong ZHANG, Yokkaichi (JP); Katsuyoshi KOMATSU, Yokkaichi (JP); Tadaomi DAIBOU, Yokkaichi (JP); Takeshi IWASAKI, Kuwana (JP); Hiroki TOKUHIRA, Kawasaki (JP); Hiroki KAWAI, Inazawa (JP); Hiroshi TAKEHIRA, Yokkaichi (JP)

(21) Appl. No.: 17/687,130

(22) Filed: Mar. 4, 2022

(30) Foreign Application Priority Data
Sep. 21, 2021 (JP) 2021-153083

(51) Int. Cl. H01L 45/00

(52) U.S. Cl. CPC H01L 45/144; H01L 45/06; H01L 45/1253

(57) ABSTRACT

A semiconductor storage device including a phase change memory film having a composition containing at least Ge, Sb, Te, and Se, and containing Se as a design composition ratio to Te in a composition ratio showing a phase change memory property with at least three elements Ge, Sb, and Te. The composition ratio of Se is 33.6 atom % or less.

### CROSS-REFERENCE TO RELATED APPLICATION

This application is based upon and claims the benefit of priority from Japanese Patent Application No. 2021-153083, filed Sep. 21, 2021, the entire contents of which are incorporated herein by reference.

### FIELD

Embodiments described herein relate generally to a semiconductor storage device.

### BACKGROUND

As a semiconductor storage device that stores a large amount of data, a resistance change-type semiconductor storage device that stores information by changing the resistance value of a memory cell is known.

### DESCRIPTION OF THE DRAWINGS

FIG. 1 is a cross-sectional view of a phase change memory element provided with a phase change memory film according to at least one embodiment.

FIG. 2 is a block diagram of a semiconductor storage device according to at least one embodiment to which the phase change memory film is applied.

FIG. 3 is a circuit diagram showing a configuration of a memory cell array of the semiconductor storage device according to at least one embodiment.

FIG. 4 is a perspective view showing a configuration of a memory cell array of the semiconductor storage device according to at least one embodiment.

FIG. 5 is a cross-sectional view taken along line AA of FIG. 3.

FIG. 6 is a cross-sectional view taken along line BB of FIG. 3.

FIG. 7 is a graph showing an example of test results of Examples before heat treatment.

FIG. 8 is a graph showing an example of test results of Examples after heat treatment

FIG. 9 is a graph showing an example of test results of Examples.

FIG. 10 is a graph showing an example of test results of Examples.

FIG. 11 is a graph showing an example of test results of Examples.

FIG. 12 is a graph showing an example of test results of Examples.

FIG. 13 is a graph showing an example of test results of Examples.

FIG. 14 is a graph showing an example of test results of Examples.

FIG. 15 is a graph showing an example of test results of Examples.

FIG. 16 is a graph showing an example of test results of Examples.

FIG. 17 is a cross-sectional view of a phase change memory element used to obtain test results of Examples.

FIG. 18 is a waveform diagram showing a test algorithm applied to the phase change memory element used in the Examples.

### DETAILED DESCRIPTION

Embodiments provide a semiconductor storage device capable of reducing a reset current.

In general, according to at least one embodiment, a semiconductor storage device includes a phase change memory film having a composition containing at least Ge, Sb, Te, and Se, and containing Se as a design composition ratio to Te in a composition ratio showing a phase change memory property with at least three elements Ge, Sb, and Te. The composition ratio of Se is 22.4 atom % or less.

Hereinafter, a semiconductor storage device including a phase change memory film and a phase change memory element according to at least one embodiment will be described with reference to the drawings. The drawings are schematic or conceptual, and the relationship between the thickness and width of each part, the ratio of the sizes between the parts, and the like are not always the same as the actual ones. In the following description, configurations having the same or similar functions are designated by the same reference numerals. Then, the duplicate description of those configurations may be omitted.

### Embodiment

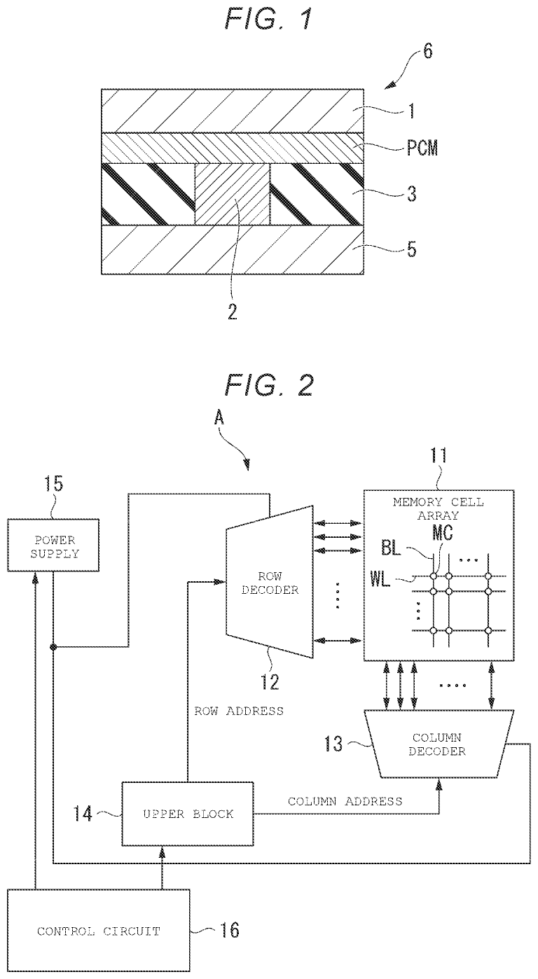

A phase change memory film PCM provided in the semiconductor storage device of the embodiment is provided between a first electrode 1 and a second electrode 2, for example, as shown in FIG. 1.

In the example of FIG. 1, the phase change memory film PCM is stacked on one surface of the layered first electrode 1, and the second electrode 2 is provided on the surface opposite to the first electrode 1 side in the phase change memory film PCM. The second electrode 2 is a columnar electrode in contact with the central part of the phase change memory film PCM.

The periphery of the second electrode 2 is covered with an insulating film 3. The insulating film 3 covers the side surface side of the second electrode 2 and is in contact with the phase change memory film PCM on the peripheral side of the second electrode 2. In the second electrode 2, an electrode layer 5 is connected to the side opposite to the phase change memory film PCM side. The electrode layer 5 is in contact with the second electrode 2 and the insulating film 3.

A phase change memory element 6 includes the first electrode 1, the second electrode 2, the phase change memory film PCM, the insulating film 3, and the electrode layer 5.

The first electrode 1, the second electrode 2, and the electrode layer 5 are made of a conductive material such as a metal material or a semiconductor material. Examples of the conductive material include tungsten (W), titanium (Ti), and polysilicon.

The phase change memory film PCM is a film whose phase structure changes depending on conditions such as temperature.

As a first example, it is preferable that the phase change memory film PCM has a composition containing at least germanium (Ge), Sb, Te, and Se, and containing Se as a design composition ratio to Te in a composition ratio showing a phase change memory property with at least three elements Ge, Sb, and Te, in which the composition ratio of Se is 33.6 atom % or less. As the first example of the phase change memory film PCM, a GeSbTeSe-based memory film may be exemplified. In addition, Se may be contained in a state where a part of Te is replaced.

As a second example, it is preferable that the phase change memory film PCM has a composition containing at least Ge, Sb, Te, Se, and N, and containing Se as a design composition ratio to Te in a composition ratio showing a phase change memory property with at least three elements Ge, Sb, and Te, in which the composition ratio of Se is 22.4 atom % or less. As the second example of the phase change memory film PCM is a GeSbTeSeN-based memory film may be exemplified. In addition, Se may be contained in a state where a part of Te is replaced.

As a third example, it is preferable that the phase change memory film PCM has a composition containing at least Sb, Te, and Se, and containing Se as a design composition ratio to Te in a composition ratio showing a phase change memory property with at least two elements Sb and Te, in which the composition ratio of Se is 33.6 atom % or less. As the second example of the phase change memory film PCM, a SbTeSe-based memory film may be exemplified. In addition, Se may be contained in a state where a part of Te is replaced.

As a fourth example, it is preferable that the phase change memory film PCM has a composition containing at least Sb, Te, Se, and N, and containing Se as a design composition ratio to Te in a composition ratio showing a phase change memory property with at least two elements Sb and Te, in which the composition ratio of Se is 22.4 atom % or less. As the fourth example of the phase change memory film PCM, a SbTeSeN-based memory film may be exemplified. In addition, Se may be contained in a state where a part of Te is replaced.

In the case of the GeSbTeSe-based phase change memory film PCM, it is preferable that the composition is represented by the following chemical formula. Here, the Se content means the Se content in a case where Se is contained as the design composition ratio to Te in the composition range showing a phase change memory property with three elements Ge, Sb, and Te. The numerical value indicating the composition ratio means (is in) atom %. Ge₂₂₊ₓSb_{22+y}Te_{56-x-y} means the composition range in a case of showing a phase change memory property with three elements Ge, Sb, and Te. Further, the Ge content and Sb content may be in the range increased or decreased by ±5 atom % with respect to 22 atom %. That is, each of Ge and Sb may be contained in the range of 17 atom % or more and 27 atom % or less.

Ge₂₂₊ₓSb_{22+y}Te_{56-x-y}Se_{z} (−5<x<+5, −5<y<+5, Z=x+y, Z≤33.6)

The upper limit of the Se content is preferably 33.6 atom % or less, more preferably 28 atom % or less, and even more preferably 16.8 atom % or less. The lower limit of the Se content needs to exceed 0 atom %, preferably 1 atom % or more, and more preferably 5.6 atom % or more. For example, a range of 5.6 atom % or more and 16.8 atom % or less may be selected.

It may be confirmed in a test example described later that the phase change memory film PCM having the above composition ratio functions as a phase change memory film by setting the Se content in the range of 16.8 atom % or less in a state where no heat treatment is performed after the film formation. Further, it may be confirmed in a test example described later that when the heat treatment is performed at 250° C. for 30 minutes after the film formation, the phase change memory film PCM functions as a phase change memory film by setting the Se content in the range of 28.0 atom % or less.

In the case of the GeSbTeSe-based phase change memory film PCM, the composition represented by the following chemical formula may also be adopted. Here, the Se content means the Se content as the design composition ratio to Te content in the composition range showing a phase change memory property with three elements Ge, Sb, and Te. The numerical value indicating the composition ratio means (is in) atom %. Ge₁₄₊ₓSb_{28+y}Te_{58-x-y} means the composition range in a case of showing a phase change memory property with three elements Ge, Sb, and Te. Further, the Ge content may be increased or decreased in the range of ±5 atom % with respect to 14 atom %, and the Sb content may be selected in the range increased or decreased by ±5 atom % with respect to 28 atom %. That is, Ge may be contained in the range of 9 atom % or more and 19 atom % or less, and Sb may be contained in the range of 22 atom % or more and 33 atom % or less.

Ge₁₄₊ₓSb_{28+y}Te_{58-x-y}Se_{z} (−5<x<+5, −5<y<+5, Z=x+y, Z≤33.6)

The upper limit of the Se content is preferably 33.6 atom % or less, more preferably 28 atom % or less, and even more preferably 16.8 atom % or less. The lower limit of the Se content needs to exceed 0 atom %, preferably 1 atom % or more, and more preferably 5.6 atom % or more.

In the case of the GeSbTeSe-based phase change memory film PCM, the composition represented by the following chemical formula may also be adopted. Here, the Se content means the Se content as the design composition ratio to the Te content in the composition range showing the phase change memory property with three elements Ge, Sb, and Te, the numerical value indicating the composition ratio means the atom %, and Ge₈₊ₓSb_{33+y}Te_{59-x-y} means the composition range in a case of showing a phase change memory property with three elements Ge, Sb, and Te. Further, the Ge content may be increased or decreased in the range of ±5 atom % with respect to 8 atom %, and the Sb content may be selected in the range increased or decreased by ±5 atom % with respect to 33 atom %. That is, Ge may be contained in the range of 3 atom % or more and 13 atom % or less, and Sb may be contained in the range of 28 atom % or more and 38 atom % or less.

Ge₈₊ₓSb_{33+y}Te_{59-x-y}Se_{z} (−5<x<+5, −5<y<+5, Z=x+y, Z≤33.6)

The upper limit of the Se content is preferably 33.6 atom % or less, more preferably 28 atom % or less, and even more preferably 16.8 atom % or less. The lower limit of the Se content needs to exceed 0 atom %, preferably 1 atom % or more, and more preferably 5.6 atom % or more.

According to the research of the present inventor, in the above-described GeSbTe-based ternary system or SbTe-based binary system phase change memory film, it was found that a phase change memory property may be exhibited even when the composition includes Se as the design composition ratio to Te. Moreover, it was found that the reset current may be reduced by setting the Se content within a specific amount range. Therefore, the above-described composition range may be adopted in the phase change memory film.

In the case of the GeSbTeSe-based or SbTeSe-based phase change memory film PCM, sulfur (S) may be contained. Sulfur may be replaced in the range of 0 to 100 atom % with respect to Se. Sulfur of the above-described wide range may be added because Se and S are cognate elements in the periodic table, and Se and S show the same addition effect in the phase change memory film PCM.

In the case of the GeSbTeSe-based or SbTeSe-based phase change memory film PCM, in addition to the above-described composition ratio, one or more selected from aluminum (Al), silicon (Si), carbon (C), boron (B), titanium (Ti), and O may be further contained.

Al, Si, C, B, Ti, and O are elements that promote amorphization of the phase change memory film PCM, and there is no problem when these elements are contained in the above-described phase change memory film PCM.

In the case of the GeSbTeSe-based or SbTeSe-based phase change memory film PCM, in addition to the above-described composition, N may be contained. When N is contained in the GeSbTeSeN-based or SbTeSeN-based phase change memory film PCM, a manufacturing method in which nitrogen gas is supplied in a film forming atmosphere and film formation is performed in a nitrogen gas flow atmosphere may be adopted. When forming a film in a nitrogen gas flow atmosphere, the condition of forming a film in a 5% nitrogen gas flow atmosphere may be adopted as an example.

A GeSbTeSeN-based phase change memory film PCM is a phase change memory film having a composition containing at least Ge, Sb, Te, Se, and N, and containing Se as a design composition ratio to Te in a composition ratio showing a phase change memory property with at least three elements Ge, Sb, and Te, in which the composition ratio of Se is 22.4 atom % or less.

A SbTeSeN-based phase change memory film PCM is a phase change memory film having a composition containing at least Sb, Te, Se, and N, and containing Se as a design composition ratio to Te in a composition ratio showing phase change memory property with at least two elements Sb and Te, in which the composition ratio of Se is 22.4 atom % or less.

It may be confirmed that the GeSbTeSeN-based phase change memory film PCM operates as a phase change memory film, as shown in the test results described later, even if Se of the range of 22.4 atom % or less is added to a sample with a film formed without heat treatment.

It may be confirmed that the GeSbTeSeN-based phase change memory film PCM operates as a phase change memory film, as shown in the test results described later, even if Se of the range of 22.4 atom % or less is added to the sample after the heat treatment at 250° C. for 30 minutes.

The phase change memory element 6 shown in FIG. 1 is used by applying a voltage applied to the phase change memory film PCM from a power source (not shown) via the first electrode 1 and the second electrode 2 while adjusting the voltage.

The phase change memory film PCM exhibits a phenomenon in which the resistance changes abruptly with a threshold voltage. The phase change memory film PCM transitions to a molten state, by using the Joule heat generated by energization, and then the voltage is dropped. At that time, the phase change memory film PCM may transition to an amorphous state (reset state) in which a high resistance state is maintained, if rapid cooling quenching is performed. Further, the phase change memory film PCM may transition to a crystalline state (set state) in which a low resistance state is maintained, when crystallized through slow cooling process. Further, the transition method from the amorphous state (reset state) in which the high resistance state is maintained to the crystalline state (set state) in which the low resistance state is maintained includes a method of achieving a crystalline state (set state) by heating at a temperature lower than the melting temperature and higher than the crystallization temperature and slowly cooling. It may be explained that the phase change memory film PCM is a storage substance that may be switched between the resistivity in the high resistance state and the resistivity in the low resistance state by heating by energization.

Utilizing these phenomena, the memory property of the phase change memory film PCM may be obtained by energization.

The rewriting operation of lowering the resistance may be called a “set operation”, the state of low resistance may be called a “set state”, the rewriting operation of increasing the resistance may be called a “reset operation”, and the state of high resistance may be called a “reset state”.

Since both the set state and the reset state are maintained even if there is no external energy supply, the phase change memory element 6 functions as a non-volatile memory.

In the phase change memory element 6 having the configuration shown in FIG. 1, the phase change memory film PCM in contact with the second electrode 2 undergoes a resistance change as described above. The central portion of the phase change memory film PCM in contact with the second electrode 2 may be partially melted by Joule heat, and the high resistance state of the phase change memory film PCM may be maintained by rapid cooling quenching in the molten state.

The phase change memory element 6 having the configuration shown in FIG. 1 has a composition containing Se with respect to the phase change memory film of the GeSbTe-based ternary system or the SbTe-based binary system, thereby reducing the reset current when performing the reset operation.

The GeSbTe-based or SbTe-based phase change memory material has a composition containing Se, which leads to an increase in set resistance (Rset) and reset resistance (Rreset). Therefore, Joule heat may be efficiently generated, so that a molten state may be easily created. Accordingly, the reset current (Ireset) may be reduced.

As an example of the mechanism that increases the set resistance (Rset) and the reset resistance (Rreset) by containing Se as the design composition ratio to Te, there is an effect due to the formation of the high bandgap substance Ge—Se by adding Se. Alternatively, it is considered that this is due to the localization of the bandgap due to the amorphous structure.

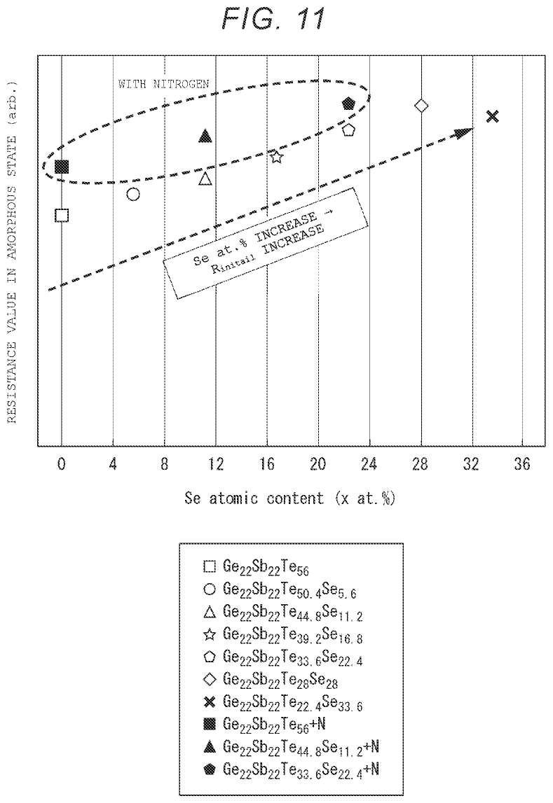

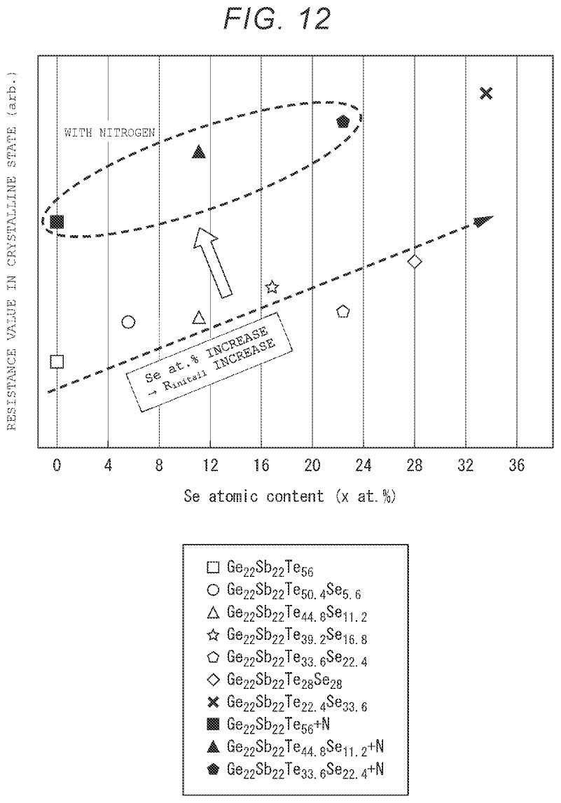

In fact, FIGS. 11 and 12 show the resistance value in the amorphous state and the resistance value in the crystalline state with respect to the Se composition, respectively. As the Se composition increases, the resistance value increases in each case, and the effect of Se may be confirmed.

Here, the reset current (Ireset) is an upper limit value of the current required to transition from the molten state to the amorphous state (reset state) in which the high resistance state is maintained. Here, when transitioning from the molten state to the crystalline state (set state) in which the low resistance state is maintained, the upper limit of the required current value is also the current value for implementing the molten state. Therefore, the effect expected in the present disclosure is not limited to the transition from the molten state to the amorphous state (reset state) in which the high resistance state is maintained. For example, the effect of reducing the current value may be expected even in the transition to the set state implemented through melting.

Further, the same effect may be expected by adding Al, Si, C, B, Ti, and Si to the GeSbTeSe-based or SbTeSe-based phase change memory film. Therefore, if the phase change memory material obtained by adding any one or more of Al, Si, C, B, Ti, and Si to the above-described phase change memory film PCM is used, the set resistance (Rset) and the reset resistance (Rreset) are increased, so that the reset current (Ireset) may be reduced, for example.

By adding nitrogen (N) to the above-described phase change memory film PCM, the crystal size may be reduced in the crystalline state. Further, nitrides of Ge, Sb, and Se are formed. It is confirmed by first-principles calculation that the nitrides of Ge, Sb, and Se have a large energy gap. Therefore, the addition of N leads to an increase in the set resistance (Rset) and the reset resistance (Rreset) (FIGS. 11 and 12), and Joule heat may be efficiently generated, so that, for example, the reset current (Ireset) may be reduced.

### Embodiment of Semiconductor Storage Device

Hereinafter, a specific example of the semiconductor storage device provided with the phase change memory film having the above-described composition will be described with reference to the drawings.

In the following description, configurations having the same or similar functions are designated by the same reference numerals. Then, the duplicate description of those configurations may be omitted. As used herein, the term “connection” is not limited to the case of being physically connected, but also includes the case of being electrically connected. As used herein, the term “adjacent” is not limited to the case where they are adjacent to each other, but includes the case where another element is present between two elements of interest. In the present specification, “xx is provided on yy” is not limited to the case where xx is in contact with yy, but also includes the case where another member is interposed between xx and yy. As used herein, the terms “parallel” and “orthogonal” also include the cases of “substantially parallel” and “substantially orthogonal”, respectively.

Further, an X direction, a Y direction, and a Z direction are defined first. The X direction and the Y direction are directions along the surface of the semiconductor substrate SB described later. The X direction is the direction in which the word line WL described later extends. The Y direction is a direction that intersects (for example, is orthogonal to) the X direction. The Y direction is the direction in which the bit line BL described later extends. The Z direction (first direction) is a direction that intersects (for example, is orthogonal to) the X direction and the Y direction, and is a thickness direction of the semiconductor substrate SB. In the present specification, the “+Z direction” may be referred to as “up” and the “−Z direction” may be referred to as “down”. The +Z direction and the −Z direction are 180° different from each other. Here, these expressions are for convenience only and do not specify the direction of gravity. Further, the X direction and the Y direction may be collectively referred to as the XY direction (second direction).

### 1. Overall Configuration of Semiconductor Storage Device

FIG. 2 is a block diagram showing an overall configuration of the semiconductor storage device according to the embodiment.

A semiconductor storage device A according to the embodiment includes a memory cell array 11, a row decoder 12, and a column decoder 13 that select a desired memory cell MC from the memory cell array 11. Further, the semiconductor storage device A includes an upper block decoder 14 that gives row addresses and column addresses to the decoders 12 and 13, a power supply 15 that supplies power to each unit of the semiconductor storage device A, and a control circuit 16 that controls the upper block decoder 14 and the power supply 15.

The memory cell array 11 includes a plurality of memory cell MCs each storing one-bit or a plurality-of-bits-of data. The memory cell array 11 is configured to be accessible (erase/write/read of data) by a desired memory cell MC, by applying a predetermined voltage to the desired bit line BL and word line WL selected by the row decoder 12 and the column decoder 13.

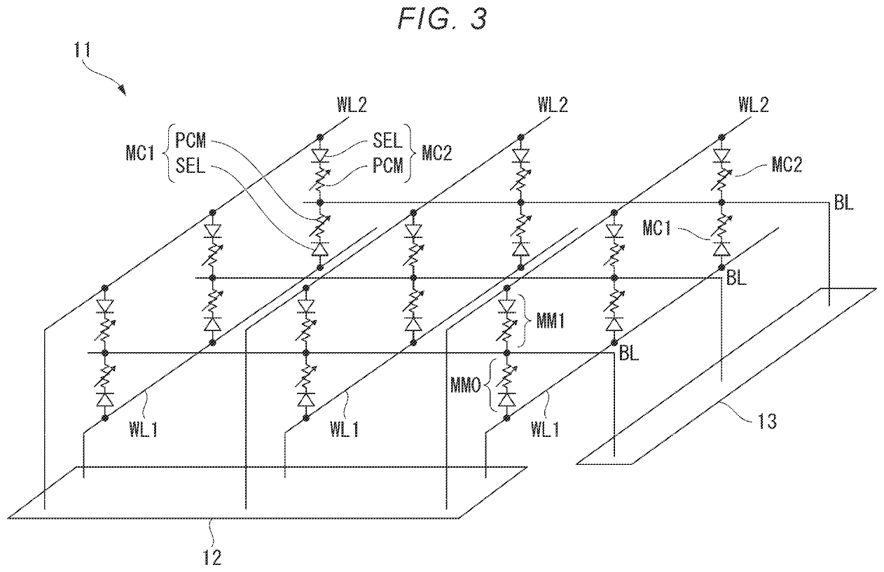

FIG. 3 is an equivalent circuit diagram showing a partial configuration of the memory cell array 11.

The memory cell array 11 includes a plurality of bit lines BL, a plurality of word lines WL1 and WL2, and a plurality of memory cells MC1 and MC2 connected to the bit line BL and the word lines WL1 and WL2.

These memory cells MC1 and MC2 are connected to the row decoder 12 via the word lines WL1 and WL2, and are connected to the column decoder 13 via the bit line BL. The memory cells MC1 and MC2 each store, for example, one-bit of data. Further, the plurality of memory cells MC1 and MC2 connected to the common word lines WL1 and WL2 store, for example, one page of data.

The memory cells MC1 and MC2 include a series circuit of a phase change memory film 23 and a selector SEL.

The phase change memory film 23 may be in two types of states including a low resistance crystalline state and a high resistance amorphous state depending on the current pattern (heating pattern), and functions as a phase change memory film. By associating these two types of resistance value states with information of “0” and “1”, the phase change memory film PCM may function as a memory cell. Therefore, the phase change memory film 23 functions as a storage layer. When the memory cells MC1 and MC2 are provided with the selectors SELs, each selector SEL functions as a rectifying element. Therefore, almost no current flows through the word lines WL1 and WL2 other than the selected word lines WL1 and WL2.

In the following, a configuration including a plurality of bit lines BL, a plurality of word lines WL1, and a plurality of memory cells MC1 corresponding to the first layer of the memory cell array 11 may be referred to as a memory mat MM0. Similarly, a configuration including a plurality of bit lines BL, a plurality of word lines WL2, and a plurality of memory cells MC2 corresponding to the second layer of the memory cell array 11 may be referred to as a memory mat MM1.

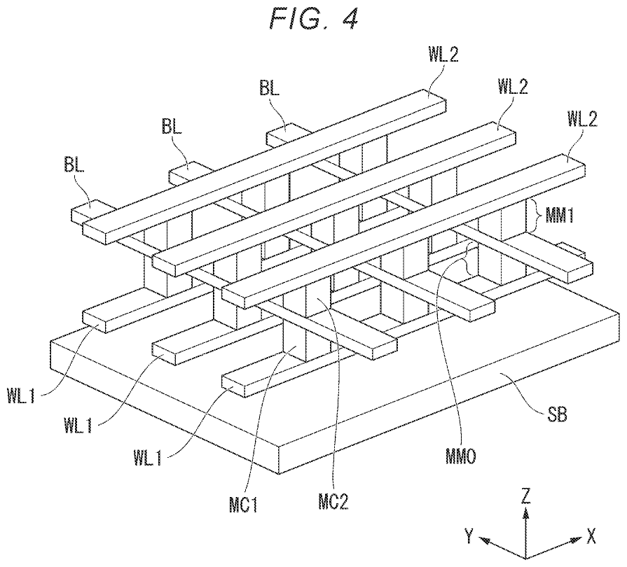

FIG. 4 is a schematic perspective view showing a partial configuration of the memory cell array 11.

The memory cell array 11 is a so-called cross-point-type memory cell array in this example. That is, a plurality of word lines WL1 are arranged above the semiconductor substrate SB at predetermined intervals in the Y direction parallel to the upper surface of the semiconductor substrate SB, and these word lines WL1 extend parallel to the upper surface of the semiconductor substrate SB and parallel to the X direction that intersects the Y direction. Further, a plurality of bit lines BL are arranged above the plurality of word lines WL1 at predetermined intervals in the X direction, and the plurality of bit lines BL extend parallel to the Y direction.

Further, a plurality of word lines WL2 are arranged above the plurality of bit lines BL at predetermined intervals in the Y direction, and the plurality of word lines WL2 extend parallel to the X direction. Further, a memory cell MC1 is provided at each of the intersections of the plurality of word lines WL1 and the plurality of bit lines BL. Similarly, a memory cell MC2 is provided at each of the intersections of the plurality of bit lines BL and the plurality of word lines WL2. In the example shown in FIG. 4, the memory cells MC1 and MC2 are each drawn in a prismatic shape. Alternatively, the memory cells MC1 and MC2 may have a columnar shape or other shapes, and their shapes are not limited.

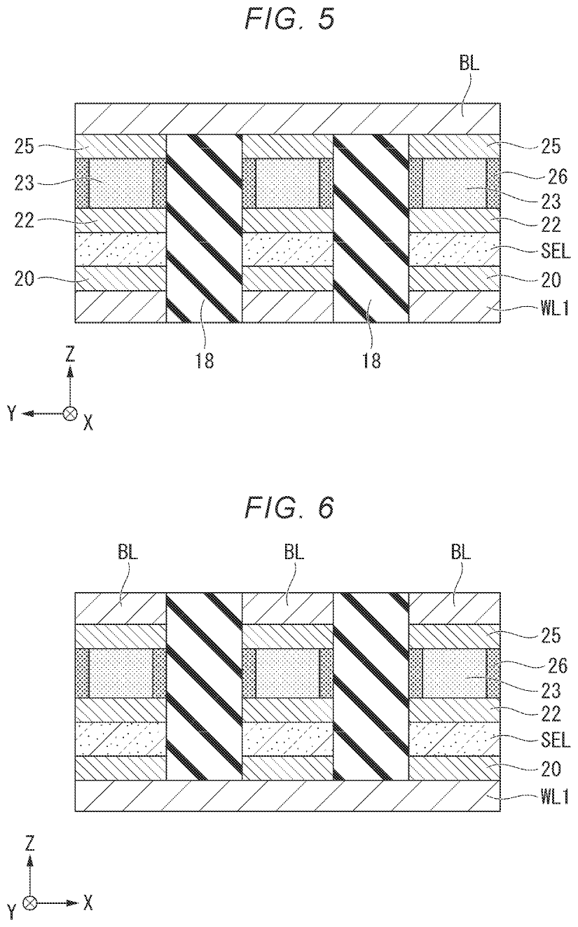

FIGS. 5 and 6 are cross-sectional views showing a part of the configuration of the memory mat MM0. FIG. 5 illustrates a cross section orthogonal to the X direction, and FIG. 6 shows a cross section orthogonal to the Y direction. FIGS. 5 and 6 show cross sections of three adjacent memory cells MC1 and their peripheral portions.

The memory mat MM0 includes a word line WL1 extending in the X direction arranged on the semiconductor substrate SB side and a bit line BL extending in the Y direction arranged opposite to the word line WL1 on the side opposite to the semiconductor substrate SB. Further, the memory mat MM0 includes a memory cell MC1 disposed between the word line WL1 and the bit line BL, and an insulating layer 18 provided between the side surfaces of the plurality of memory cells MC1 in the XY direction (second direction).

The memory cell MC1 includes a lower electrode layer (second electrode) 20, a selector SEL, an intermediate electrode layer 22, a phase change memory film (resistance change memory film, storage layer) 23, and an upper electrode layer (first electrode) 25, which are stacked in this order in the Z direction (first direction) from the word line WL1 side toward the bit line BL side. On the side surfaces (peripheral surfaces) of the phase change memory film 23 in the XY direction (second direction), protective layers (side wall layers) 26 covering these side surfaces are formed.

The word line WL1 and the bit line BL include conductive materials such as tungsten (W), titanium (Ti), and poly Si. In the examples of FIGS. 5 and 6, the lower electrode layer 20 is stacked on the word line WL1.

The insulating layer 18 includes an insulating material such as silicon oxide (SiO₂) and silicon nitride (Si₃N₄).

The selector SEL may be, for example, a switch element between two terminals. When the voltage applied between the two terminals is the threshold value or less, the switch element is in a “high resistance” state, for example, a non-conducting state. When the voltage applied between the two terminals is the threshold value or more, the switch element changes to a “low resistance” state, for example, an electrically conductive state. The switch element may have this function regardless of the polarity of the voltage. This switch element contains at least one or more chalcogen elements selected from the group consisting of Te, Se and S. Alternatively, the switch element may contain chalcogenide, which is a compound containing the chalcogen element. The switch element may also contain at least one or more elements selected from the group consisting of B, Al, Ga, In, C, Si, Ge, Sn, As, P, and Sb.

The phase change memory film 23 is made of a material equivalent to the material applied to the above-described phase change memory film PCM.

The protective layer (side wall layer) 26 is composed of the elements, for example, at least one selected from nitrogen (N), carbon (C), boron (B) and oxygen (O) in the same material as the phase change memory film 23.

Elements such as nitrogen (N), carbon (C), boron (B) and oxygen (O) increase the melting temperature of the protective layer 26. Therefore, in at least one embodiment, for example, the melting temperature of the protective layer 26 is higher than the melting temperature of the phase change memory film 23. More specifically, the melting temperature of the protective layer 26 is higher than the heat applied to the phase change memory film 23 when accessing the memory cell MC1, for example, higher than 500° C. Therefore, the protective layer 26 is not melted by the access to the memory cell MC1 and maintains the solidified state. Further, the protective layer 26 is in an amorphous state with high resistance. Therefore, the crystallization temperature of the protective layer 26 is higher than the melting temperature of the phase change memory film 23.

The phase change memory film 23 is brought into an amorphous state (reset state) by heating at the melting temperature or higher and rapid cooling. Further, the phase change memory film 23 is brought into a crystalline state (set state) by being heated at a temperature lower than the melting temperature and higher than the crystallization temperature and slowly cooled. Therefore, the phase change memory film 23 is repeatedly melted and solidified by the reset and set.

Therefore, it may be explained that the phase change memory film 23 is a storage substance that may be switched between the resistivity in the high resistance state and the resistivity in the low resistance state by heating by energization.

In the semiconductor storage device A shown in FIGS. 2 to 6, the phase change memory film PCM may obtain at least two resistance values in a bistable state at room temperature, by applying a voltage or supplying a current. By writing and reading these two stable resistance values, at least two memory operations may be achieved. When the binary memory operation is performed, for example, the low resistance state of the phase change memory film PCM may be correlated with “1” and the high resistance state may be associated with “0”.

Since the semiconductor storage device A has a plurality of phase change memory film PCMs, information may be stored in the individual phase change memory film PCMs.

Since the semiconductor storage device A includes the phase change memory film 23 equivalent to the above-described phase change memory film PCM, the set resistance (Rset) may be increased and the reset current (Ireset) may be reduced.

In addition, since the semiconductor storage device A includes the phase change memory film 23 made of the same material as the phase change memory film PCM described above, an effect equivalent to the effect obtained from the phase change memory film PCM described above may be obtained. Examples

Hereinafter, examples will be described.

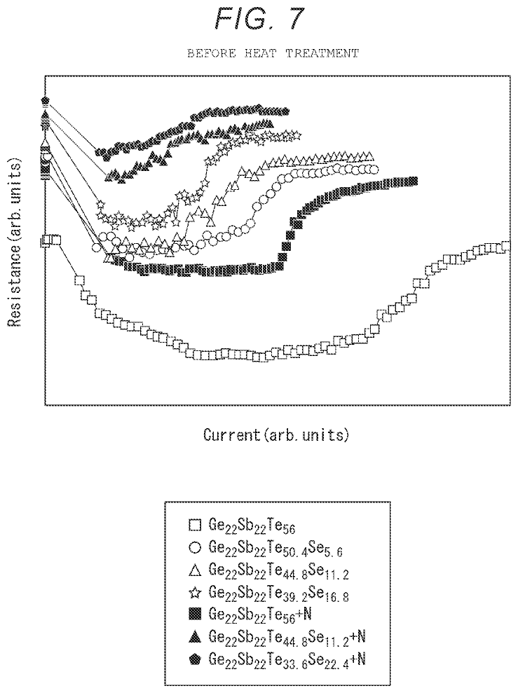

FIGS. 7 to 16 show the characteristics obtained as a result of the energization test mainly using the phase change memory element of the example described below.

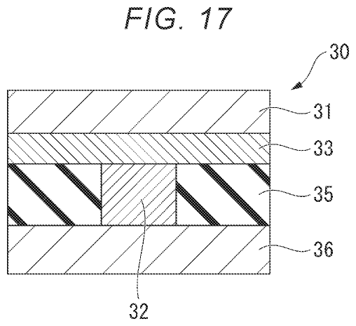

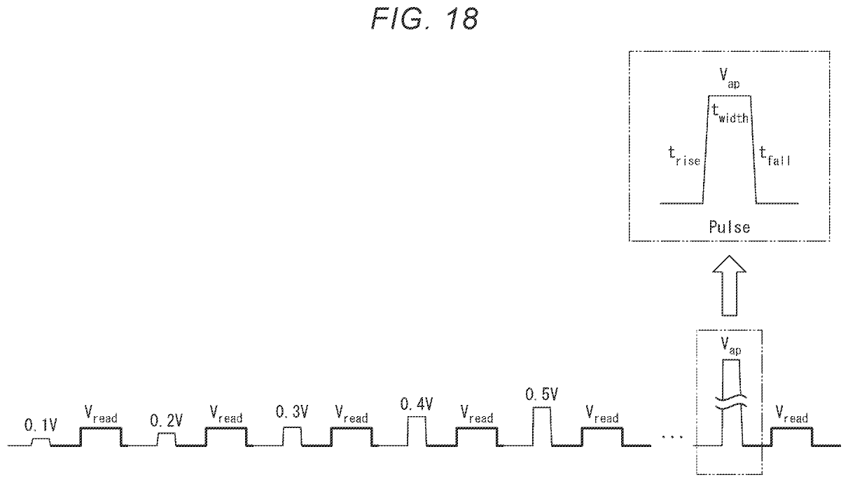

These tests were performed by using a phase change memory element having the structure shown in FIG. 17 and performing an energization test in which a pulse voltage was applied to the phase change memory element by the test algorithm shown in FIG. 18.

A phase change memory element 30 shown in FIG. 17 has the same configuration as the phase change memory element 6 shown in FIG. 1. The phase change memory element 30 has a structure in which a phase change memory film 33 is sandwiched between a layered first electrode 31 and a columnar second electrode 32. The columnar second electrode 32 is formed in the central portion of an insulating film 35. The second electrode 32 is connected to an electrode layer 36 formed on the outer surface of the insulating film 35 and is connected to a power source (not shown) via the electrode layer 36, and this power source is connected to the first electrode 31.

It is possible to switch between a high resistance state and a low resistance state by performing an energization process using the first electrode 31 and the second electrode 32, melting the area around the portion of the phase change memory film 33 in which the second electrode 32 is in contact, and rapidly cooling or gradually cooling after melting.

The thickness of the phase change memory film 33 is about 50 nm, the second electrode is formed in a columnar shape having a diameter of 100 to 200 nm, an electrode layer made of W, TiN, C, and Ti was used as the first electrode, and an electrode made of W was used as the second electrode.

The constituent material of the phase change memory film 33 was composed of a material described later. The test algorithm shown in FIG. 18 supplied a short pulse and read the resistance at a low voltage (Vread).

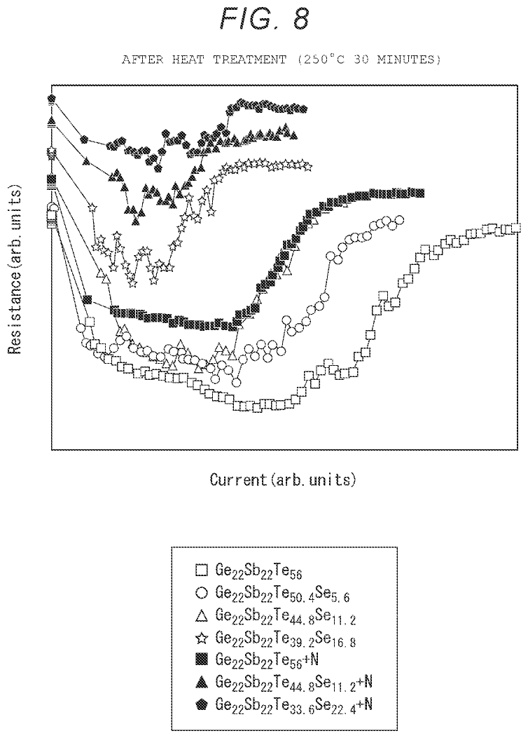

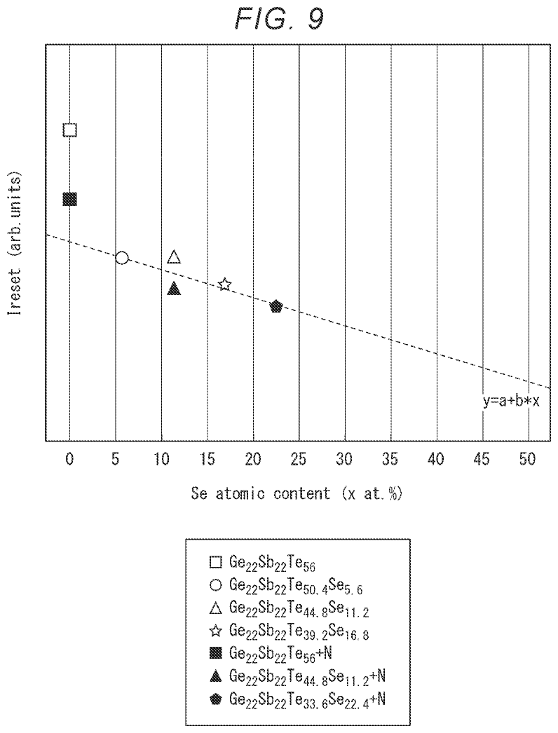

FIGS. 7 and 8 are graphs showing the results of measuring the relationship between the resistance value and the current value for a plurality of samples having different compositions, when the GeSbTe-based phase change memory film is applied to the structure shown in FIG. 17. FIG. 9 shows the results of measuring the relationship between the reset current and the Se content (atom %) in the same sample.

For a plurality of samples having different compositions, any one of Ge₂₂Sb₂₂Te₅₆, Ge₂₂Sb₂₂Te_{50.4}Se_{5.6}, Ge₂₂Sb₂₂Te_{44.8}Se_{11.2}, Ge₂₂Sb₂₂Te_{39.2}Se_{16.8}, Ge₂₂Sb₂₂Te_{33.6}Se_{22.4}, Ge₂₂Sb₂₂Te₂₈Se₂₈ , Ge₂₂Sb₂₂Te_{22.4}Se_{33.6}, Ge₂₂Sb₂₂Te₅₆+N, Ge₂₂Sb₂₂Te_{44.8}Se_{11.2}+N, and Ge₂₂Sb₂₂Te_{33.6}Se_{22.4}+N was used. In the above chemical formula, the sample described as +N indicates that the sample was formed while flowing 5% nitrogen gas at the time of film formation.

Further, for the formation of these samples, for example, a film forming method such as a sputtering method, a vapor deposition method, an atomic layer deposition (ALD) method, or a chemical vapor deposition (CVD) method may be applied.

When a phase change memory film composed of Ge, Sb, Te, and Se is formed by a sputtering method, it may be formed using, for example, a GeSbTeSe target whose composition is adjusted. Alternatively, it may be formed by simultaneously sputtering (cosputtering) the GeSb target and the TeSe target, or by alternately stacking the GeSb target and the TeSe target.

The composition of the elements may be controlled by adjusting the composition of the target to be used, the input power during film formation, the film formation gas pressure, the distance between the substrate and the target, and the film formation time.

The combination of targets used at that time depends on the elements, and is not limited to the combination of targets listed here as an example. Further, for the phase change memory film containing nitrogen, composed of Ge, Sb, Te, Se, and N, a GeSbTeSeN film may be formed by a method using a GeSbTeSeN sputter target of which composition is adjusted, or by exposing GeSbTeSe in a nitrogen atmosphere or nitrogen plasma during or after film formation by the above method, or by a combination thereof.

Considering that Se is contained as the design composition ratio to Te, the Se content is expressed in atom %, and it may be represented by the chemical formula Ge₂₂Sb₂₂Te₅₆₋ₓSeₓ. When the Se content is 6 atom %, this chemical formula becomes Ge₂₂Sb₂₂Te₅₀Se₆. When the Se content is 11 atom %, this chemical formula becomes Ge₂₂Sb₂₂Te₄₅Se₁₁.

In the composition of Ge₂₂Sb₂₂Te₅₆₋ₓSeₓ, as the Se content increases, resistance and Eg are expected to increase. This is because the formation of Ge—Se bonds increases the Bond energy of the entire composition.

As shown in FIGS. 7 and 8, it is clear that the phase change memory film having any composition shows a low resistance state and a high resistance state according to the current value, and it may be seen that the phase change memory film may be used as the resistance change memory film. In the graphs of FIG. 7 and subsequent drawings, arb.units indicates an arbitrary unit.

As shown in FIG. 9, compared with the sample of Ge₂₂Sb₂₂Te₅₆, it was found that increasing the Se content from 5.6 atom % to 16.8 atom % in the sample of Ge₂₂Sb₂₂Te₅₆₋ₓSeₓ could reduce the reset current (Ireset) by 42% to 55%.

As shown in FIG. 9, it was found that the reset current (Ireset) may be further reduced in the sample obtained by applying nitrogen doping (5% nitrogen flow with respect to Ar flow) to Ge₂₂Sb₂₂Te₅₆₋ₓSeₓ (x=0, 11.2, 22.4 atom %). These samples were found to be able to reduce the reset current by 53% to 61% by comparison with Ge₂₂Sb₂₂Te₅₆.

For samples in the composition range represented by Ge₂₂Sb₂₂Te₂₈Se₂₈ and Ge₂₂Sb₂₂Te_{22.4}Se_{33.6}, the reduction in reset current (Ireset) was small. When Se of an amount of more than 28 atom % was contained in the sample of the composition range represented by Ge₂₂Sb₂₂Te₅₆₋ₓSeₓ, the reduction of the reset current (Ireset) was small. Therefore, when using the GeSbTe-based and the SbTe-based phase change memory films containing Se, it was found that the Se content is preferably 22.4 atom % or less in the nitrogen-doped sample, and the Se content is preferably 16.8 atom % or less in the non-nitrogen-doped sample.

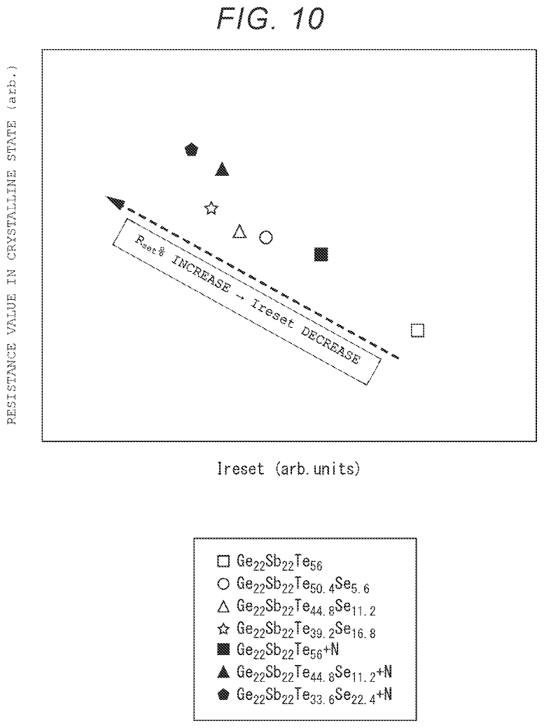

FIG. 10 shows the results of measuring the resistance dependence in the crystalline state on the Se content (atom %), with respect to a plurality of samples having different compositions in the GeSbTe-based phase change memory film.

It may be seen from FIG. 10 that the reset current (Ireset) may be reduced as the set resistance (Rset) increases.

FIG. 11 shows the results of measuring the resistance dependence in the amorphous state on the Se content (atom %), with respect to a plurality of GeSbTe-based samples having different compositions.

It was found that in the sample of the composition range represented by Ge₂₂Sb₂₂Te₅₆₋ₓSeₓ, as the Se content that replaces Te increases, the resistance of the sample in the amorphous state increases.

It was found that the resistance in the amorphous state may be further improved by performing nitrogen doping (5% nitrogen flow with respect to Ar flow) on the sample in the composition range represented by Ge₂₂Sb₂₂Te₅₆₋ₓSeₓ (x=0, 11.2, 22.4 atom %).

FIG. 12 shows the results of measuring the resistance dependence in the crystalline state on the reset current, with respect to a plurality of samples having different compositions in the GeSbTe-based phase change memory film.

It was found that with respect to the samples of the composition range represented by Ge₂₂Sb₂₂Te₅₆₋ₓSeₓ and the samples of the composition range represented by Ge₂₂Sb₂₂Te₅₆₋ₓSeₓ+N, as the Se content increases, the resistance in the crystalline state increases and the reset current decreases.

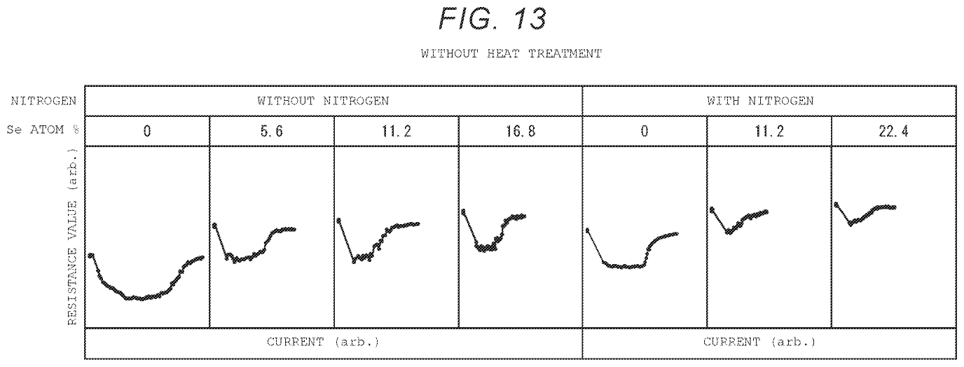

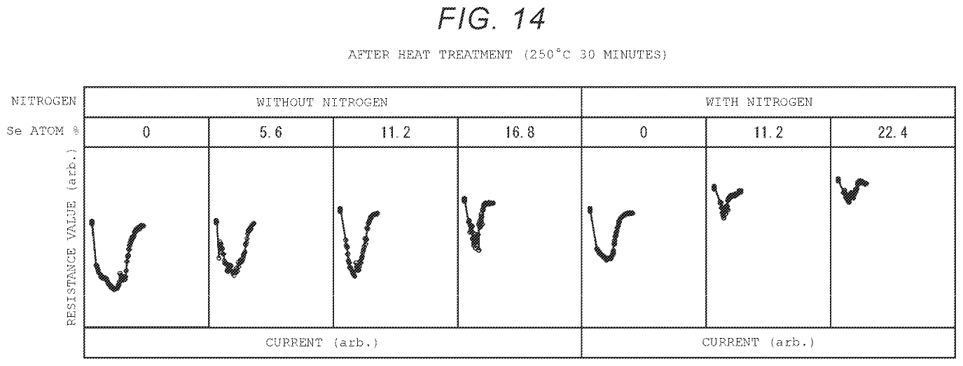

FIG. 13 shows the results of measuring R-I characteristics of the sample in the composition range represented by Ge₂₂Sb₂₂Te₅₆₋ₓSeₓ and the sample in the composition range represented by Ge₂₂Sb₂₂Te₅₆₋ₓSeₓN, in the sample without heat treatment, and FIG. 14 shows the results of measuring the R-I characteristics of the sample heat-treated at 250° C. for 30 minutes.

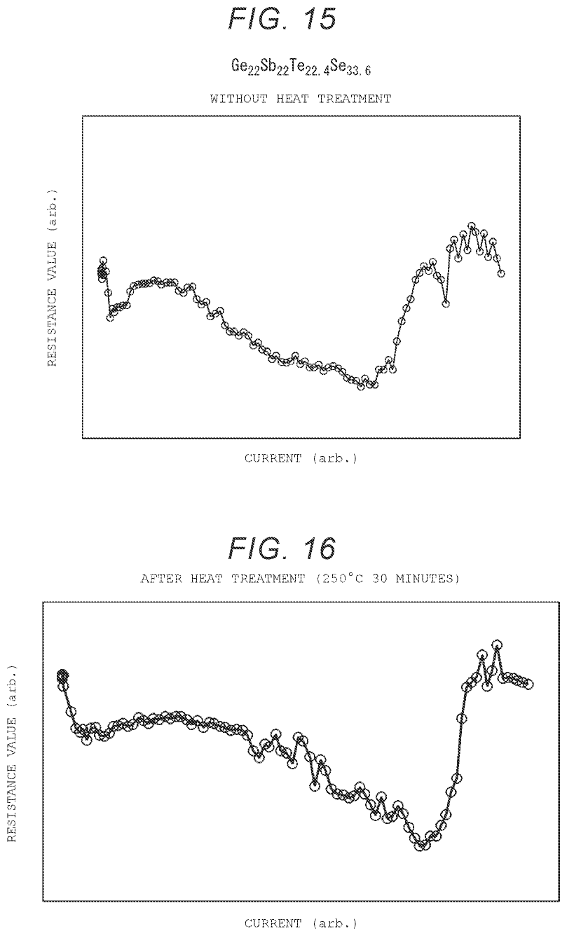

FIG. 15 shows the results of measuring the R-I characteristics of the sample (without heat treatment) having the composition indicated by Ge₂₂Sb₂₂Te_{22.4}Se_{33.6}.

FIG. 16 shows the results of measuring the R-I characteristics of the sample having the composition indicated by Ge₂₂Sb₂₂Te_{22.4}Se_{33.6} after heat treatment at 250° C. for 30 minutes.

It was found that with respect to the sample in the composition range represented by Ge₂₂Sb₂₂Te₅₆₋ₓSeₓ, samples with a Se content of 0 atom % or more and 16.8 atom % or less operate as a phase change memory film, and the Ireset current decreases as compared with 0 atom %, when the Se content is increased.

In addition, it may be confirmed that even if a heat treatment at 250° C. for 30 minutes is added, the effect of reducing the Ireset current compared to 0 atom % with respect to the increase in Se content is maintained up to 16.8 atom % of Se content (FIG. 14). It was also found that the film operates as a phase change memory film up to a Se content of 33.6 atom % regardless of heat treatment (FIG. 15).

It was found that with respect to the sample indicated by Ge₂₂Sb₂₂Te₅₆₋ₓSeₓN doped with nitrogen, a sample to which Se in the range of 22.4 atom % or less is added operates as a phase change memory film, and the Ireset current decreases as compared with the Se content of 0 atom % (FIG. 13).

In addition, it was found that even if a heat treatment at 250° C. for 30 minutes is added, the effect of reducing the Ireset current compared to 0 atom % with respect to the increase in Se content is maintained up to 22.4 atom % of Se content (FIG. 14).

A plurality of embodiments and modifications are described above. It is noted that the embodiments are not limited to the above examples. For example, the plurality of embodiments and modifications described above may be implemented in combination with each other.

According to at least one embodiment described above, the phase change memory film showing a GeSbTeSe-based phase change memory property has the composition ratio of Se equal to or less than 28 atom %, thereby reducing the reset current.

According to at least one embodiment described above, the phase change memory film showing a SbTeSe-based phase change memory property has the composition ratio of Se equal to or less than 28 atom %, thereby reducing the reset current.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising a phase change memory film having a composition containing at least Ge, Sb, Te, and Se, wherein a composition ratio of the Se is 33.6 atom % or less.

2. A semiconductor storage device comprising a phase change memory film having a composition containing at least Ge, Sb, Te, Se, and N, wherein a composition ratio of the Se is 22.4 atom % or less.

3. A semiconductor storage device comprising a phase change memory film having a composition containing at least Sb, Te, and Se, wherein a composition ratio of the Se is 33.6 atom % or less.

4. A semiconductor storage device comprising a phase change memory film having a composition containing at least Sb, Te, Se, and N, wherein a composition ratio of the Se is 22.4 atom % or less.

5. The semiconductor storage device according to claim 1, wherein the phase change memory film has a composition ratio represented by a chemical formula Ge₂₂₊ₓSb_{22+y}Te_{56-x-y}Se_{z} (−5<x<+5, −5<y<+5, Z=x+y, Z≤33.6),
wherein a numerical value indicating the composition ratio is in atom %.

6. The semiconductor storage device according to claim 1, wherein the phase change memory film has a composition ratio represented by a chemical formula Ge₁₄₊ₓSb_{28+y}Te_{58-x-y}Se_{z} (−5<x<+5, −5<y<+5, Z=x+y, Z≤33.6),
wherein, a numerical value indicating the composition ratio is in atom %.

7. The semiconductor storage device according to claim 1, wherein the phase change memory film has a composition ratio represented by a chemical formula Ge₈₊ₓSb_{33+y}Te_{59-x-y}Se_{z} (−5<x<+5, −5<y<+5, Z=x+y, Z≤33.6),
wherein, a numerical value indicating the composition ratio is in atom %.

8. The semiconductor storage device according to claim 1, wherein the phase change memory film contains S.

9. The semiconductor storage device according to claim 1, wherein the phase change memory film contains one or more elements selected from Al, Si, C, B, Ti, or O.

10. A semiconductor storage device comprising:
a first electrode;
a second electrode; and
a phase change memory film disposed between the first electrode and the second electrode, wherein
the phase change memory film has a composition containing at least Ge, Sb, Te, and Se, and a composition ratio of the Se is 33.6 atom % or less.

11. A semiconductor storage device comprising:
a first electrode;
a second electrode; and
a phase change memory film disposed between the first electrode and the second electrode, wherein
the phase change memory film has a composition containing at least Ge, Sb, Te, Se, and N, and a composition ratio of the Se is 22.4 atom % or less.

12. A semiconductor storage device comprising:
a first electrode;
a second electrode; and
a phase change memory film disposed between the first electrode and the second electrode, wherein
the phase change memory film has a composition containing at least Sb, Te, and Se, and a composition ratio of the Se is 33.6 atom % or less.

13. A semiconductor storage device comprising:
a first electrode;
a second electrode; and
a phase change memory film disposed between the first electrode and the second electrode, wherein
the phase change memory film has a composition containing at least Sb, Te, Se, and N, and a composition ratio of the Se is 22.4 atom % or less.

14. The semiconductor storage device according to claim 10, wherein
the phase change memory film has a composition ratio represented by a chemical formula Ge₂₂₊ₓSb_{22+y}Te_{56-x-y}Se_{z} (−5<x<+5, −5<y<+5, Z=x+y, Z≤33.6).

15. The semiconductor storage device according to claim 10, wherein
the phase change memory film has a composition ratio represented by a chemical formula Ge₁₄₊ₓSb_{28+y}Te_{58-x-y}Se_{z} (−5<x<+5, −5<y<+5, Z=x+y, Z≤33.6).

16. The semiconductor storage device according to claim 10, wherein
the phase change memory film has a composition ratio represented by a chemical formula Ge₈₊ₓSb_{33+y}Te_{59-x-y}Se_{z} (−5<x<+5, −5<y<+5, Z=x+y, Z≤33.6).

17. The semiconductor storage device according to claim 10, wherein the phase change memory film further comprises S.

18. The semiconductor storage device according to claim 10, wherein the phase change memory film further comprises:
one or more elements selected from Al, Si, C, B, Ti, or O.

19. The semiconductor storage device according to claim 10, wherein the second electrode is a columnar electrode in contact with a central portion of the phase change memory film.

20. The semiconductor storage device according to claim 11, wherein the second electrode is a columnar electrode in contact with a central portion of the phase change memory film.
